(19) United States
(12) Patent Application Publication
(10) Pub. No.: US 2025/0370010 A1
(43) Pub. Date: Dec. 4, 2025

(54) LOW POWER INSTRUMENT TRANSFORMER (LPIT) IN CONICAL CONNECTOR

(71) Applicant: Siemens Energy Global GmbH & Co. KG, München (DE)

(72) Inventors: Stefan Beutel, Berlin (DE); Andreas Heiko Kloos, Brieselang (DE)

(21) Appl. No.: 18/874,104

(22) PCT Filed: Jun. 14, 2023
(86) PCT No.: PCT/US2023/068396

§ 371 Date: Dec. 12, 2024

Related U.S. Application Data
(60) Provisional application No. 63/356,582, filed on Jun. 29, 2022.

(51) Int. Cl. G01R 15/18; G01R 19/00

(52) U.S. Cl. CPC G01R 15/181; G01R 19/0092

(57) ABSTRACT

A sensor arrangement for a gas-insulated switchgear is provided. The sensor arrangement includes a connector having a housing defining a hollow interior, a current conductor passing through the interior of the housing, a low power instrument transformer, a shielding field electrode, and a resin. The low power instrument transformer includes an electrode having a ring shape and including a voltage sensor for measuring a voltage of the current conductor. The low power instrument transformer also includes a current sensor positioned to measure a current of the current conductor. The shielding field electrode is disposed between the current sensor and the current conductor. The resin cooperates with and surrounds the current conductor, the voltage sensor, the current sensor and the shielding field electrode to fill the hollow interior.

### BACKGROUND

The present application relates to a low power instrument transformer arrangement including a voltage sensor and a current sensor, wherein the voltage sensor has a measuring electrode for detecting an electrical voltage. The low power instrument transformer arrangement may be used to measure the current flowing through a current conductor.

Gas insulated switchgear (GIS) typically include an encapsulated vessel filled with a pressurized insulating gas. The pressurized vessel encloses a switch panel which includes components such as a circuit breaker, cable sealing, and a conductor(s) arranged and enclosed within the pressurized vessel. A current/voltage transformer detects an electrical current and/or an electrical voltage, respectively, within high voltage cables connected to the gas insulated switchgear.

The GIS is an important part of an electrical grid and is mainly located in areas with limited space. The connection with the grid is usually made via bushings or cables. Plug-in systems to windtower systems have taken over from medium voltage switchgears and are becoming more widespread because of less installation space and faster installation and commissioning.

Conventionally, the GIS switchgear has a current transformer which is arranged for protection purposes around the high voltage cables before the plug-in connector of the cables to the switchgear, external to the encapsulated vessel. The installation of these current transformers is time-consuming and has to be done before the installation of the high-voltage cables. The high-voltage cables have large diameters, around 80 mm, and are difficult to bend or thread through the current transformer coils.

### BRIEF SUMMARY

A sensor arrangement for a gas-insulated switchgear includes a connector having a housing defining a hollow interior, a current conductor passing through the interior of the housing, a low power instrument transformer, a shielding field electrode, and a resin. The low power instrument transformer includes an electrode having a ring shape and including a voltage sensor for measuring a voltage of the current conductor. The low power instrument transformer also includes a current sensor positioned to measure a current of the current conductor. The shielding field electrode is disposed between the current sensor and the current conductor. The resin cooperates with and surrounds the current conductor, the voltage sensor, the current sensor and the shielding field electrode to fill the hollow interior.

In another construction, a gas-insulated switchgear includes a sensor arrangement. The sensor arrangement includes a connector having a housing defining a hollow interior, a current conductor passing through the interior of the housing, a low power instrument transformer, a shielding field electrode, and a resin. The low power instrument transformer includes an electrode having a ring shape and including a voltage sensor for measuring a voltage of the current conductor. The low power instrument transformer also includes a current sensor positioned to measure a current of the current conductor. The shielding field electrode is disposed between the current sensor and the current conductor. The resin cooperates with and surrounds the current conductor, the voltage sensor, the current sensor and the shielding field electrode to fill the hollow interior.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 illustrates a sectional view of a windtower.

FIG. 2 illustrates a partial sectional view of the windtower of FIG. 1 with a gas insulated switchgear and a conventional current transformer.

FIG. 3 illustrates a sectional view of a connector with an integrated current transformer.

FIG. 4 illustrates a perspective view of the connector with the integrated current transformer of FIG. 3.

### DETAILED DESCRIPTION

The present disclosure describes a plug-in connector with integrated measurement of current and voltage based on LPIT technology for high voltage applications such as those above 45 kV. LPIT combines a low power voltage transformer and low power current transformer.

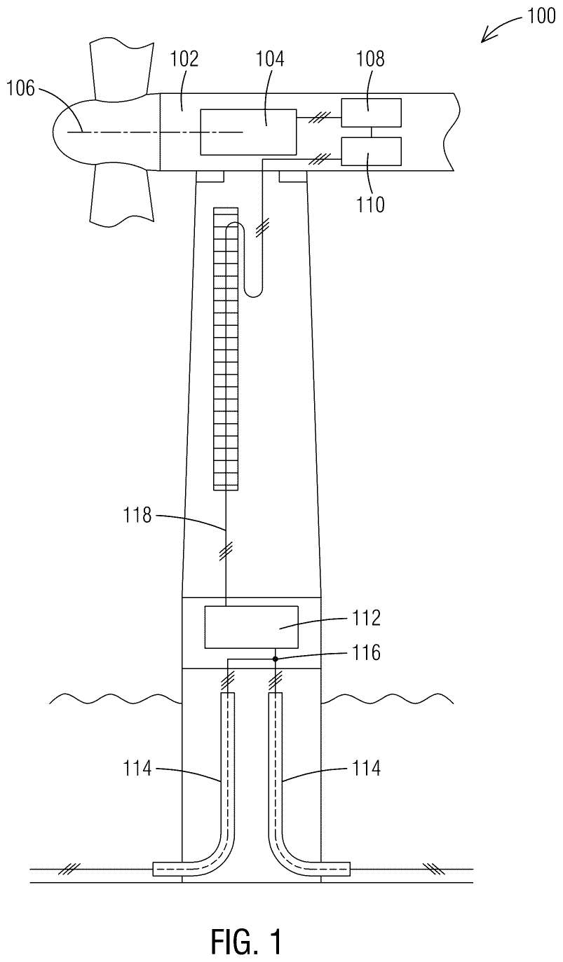

FIG. 1 is a sectional view of a windtower 100 which includes a tower resting on a base. At one end of the tower opposite the base is a nacelle 102 which supports a rotor 106. The rotor 106 is connected to a generator 104 which converts the movement of the rotor 106 into variable frequency electrical energy. The generator 104 is connected to an inverter 108 and a transformer 110 so that the electrical energy from the generator 104 can be converted into a standard value, for example 60 Hz in the United States, via the inverter 108 and the transformer 110. The transformer 110 transforms the generated energy into a transmission suitable voltage level, for example 960 VAC-6600 VAC. The transformer 110 is connected via a first cable connection 118 to a pressurized gas insulated switchgear 112. In the illustrated view of FIG. 1, the gas insulated switchgear 112 is located in the tower of the windtower 100 toward the base. While the gas insulated switchgear 112 is depicted in this case as a component of windtower 100, this is for illustrative purposes only. The gas insulated switchgear 112 may be utilized in other applications as well, such as transmission stations onshore. A second cable connection 114 connects the gas insulated switchgear 112 to an electrical energy transmission network (not shown). In the shown embodiment, the second cable connection 114 includes a node 116 that branches into two cables traveling parallel to one another.

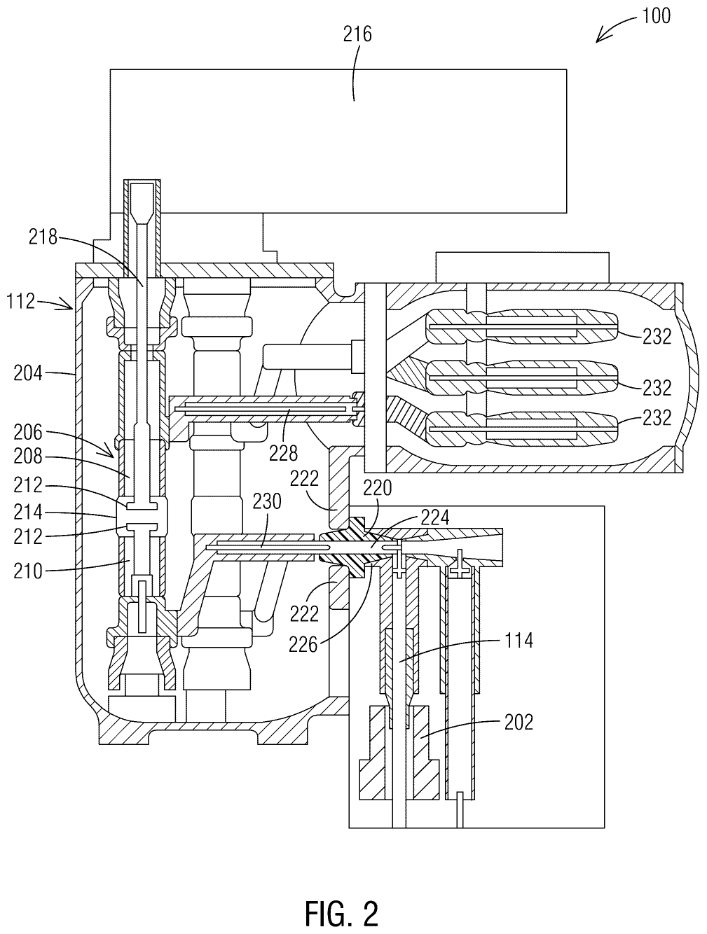

FIG. 2 is a partial sectional view of components of the windtower 100 shown in FIG. 1. The gas insulated switchgear 112 is shown in FIG. 2 with more detail. The gas insulated switchgear 112 includes a pressurized container 204. The pressurized container 204 may comprise a metal, such as aluminum, and may include a hollow cylindrical structure closed at each end in a fluid tight manner. The interior of the pressurized container 204 is filled with a fluid that is pressurized to a pressure higher than that of the pressure of the medium surrounding the pressurized container 204 so that the components located within the interior are electrically insulated. The pressurized fluid may be sulfur hexafluoride gas.

The gas insulated switchgear 112 also includes a switching device 206. The switching device 206 may be a multiphase design, where the switching paths of the individual phases may be a similar design. One phase of the switching device 206 is shown in FIG. 2 for simplicity purposes only. Each phase of the switching device 206 includes a contact making first side 208 and a contact making second side 210. Switching contact pieces 212 which are movable relative to one another are arranged between the first side 208 and the second side 210. The first side 208 and the second side 210 are connected by an electrically insulating spacer 214.

A drive device 216 arranged exterior to the gas insulated switchgear 112 is utilized to move the contact pieces 212 relative to one another via a drive rod 218 guided through the housing of the pressurized container 204 in a fluid-tight manner. Connecting conductors 228 connect the first side 208 to output lines 232 exterior to the pressurized container 204. A grounding switch arranged in the interior of the gas insulated switchgear 112 may be utilized to ground the first side 208 of the switching device 206.

A connector 220 including a housing may be used to incorporate the switching device 206 into a current path. A current conductor 224 passes through a hollow interior of the housing. The current conductor 224 may be a three phase conductor, conducting the three phases through the pressurized container 204 via connecting conductors 230 to the second side 210 of the switching device 206. The connector 220 connects to a plug 226. The plug 226 provides a point at which to connect the second cable connection 114 with the second side 210.

FIG. 2 also includes a conventional conical current transformer 202 disposed around and concentric to the second cable connection 114. Current transformers are typically used to perform current measurements on the phase conductors when a direct current measurement may be difficult to obtain. In order to install this conventional current transformer 202, the second cable connection 114 has to pass through the current transformer 202.

The inventors have recognized that a current transformer may be included within the connector 220 which connects the current conductors 224 from the gas insulated switchgear 112 to the second cable connection 114

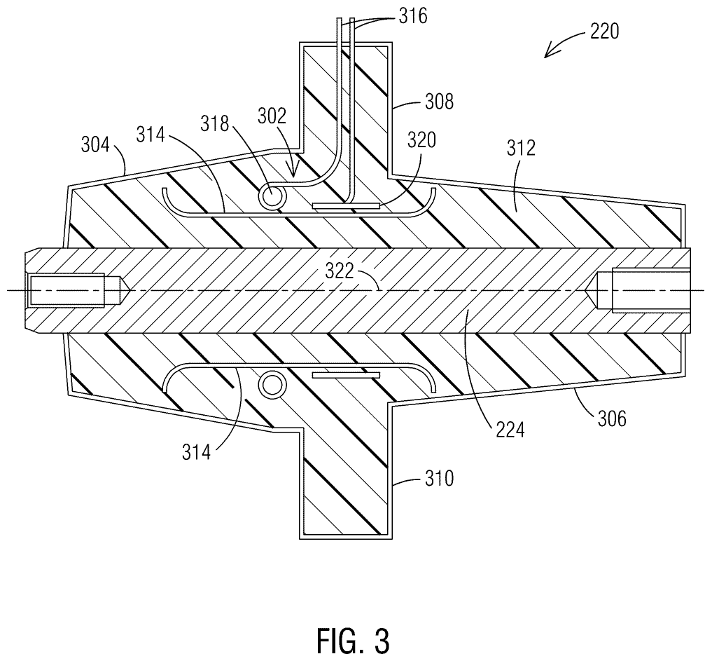

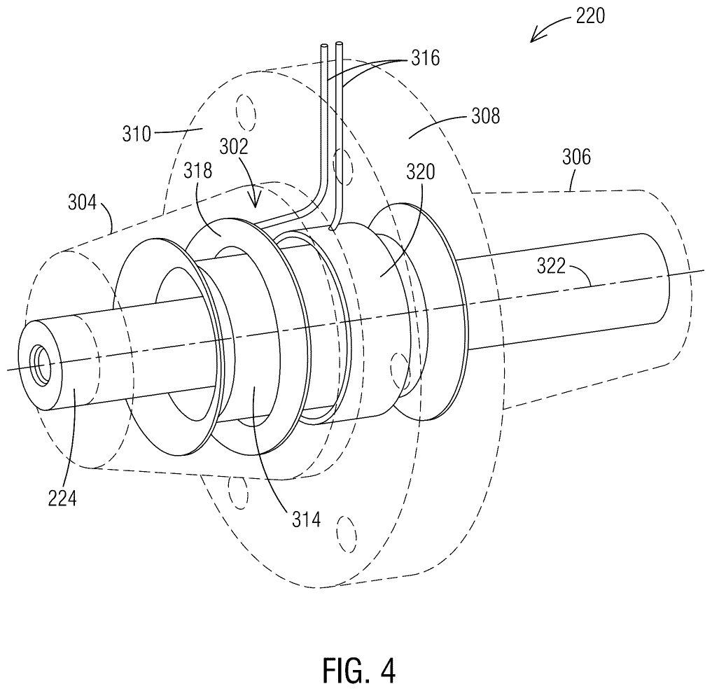

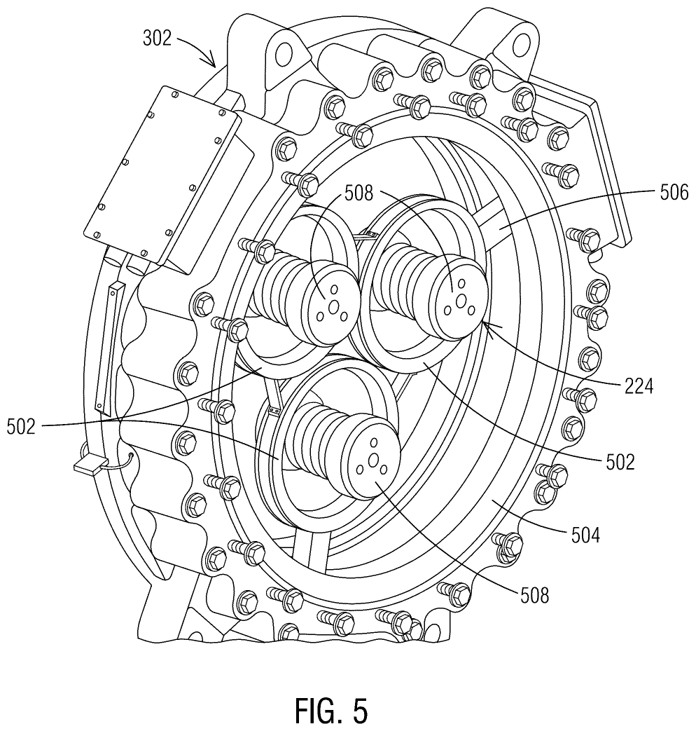

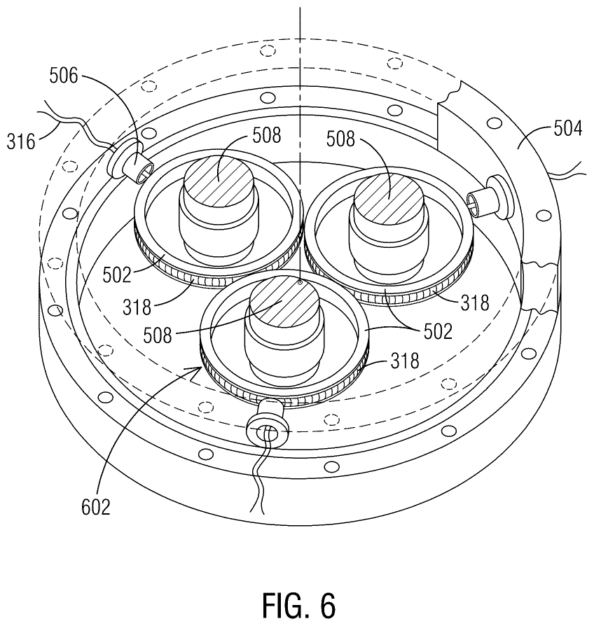

FIG. 3 illustrates a sectional view of the connector 220 of FIG. 2 including a current transformer such as a low power instrument transformer 302 (LPIT) while FIG. 4 shows a perspective view of the connector 220 with the low power instrument transformer 302 installed within its interior. LPIT works according to the principle of the instrument transformer based on the specific adaptation to an internal shunt. This principle is exceptionally insensitive to external stray fields. The secondary current produces a voltage across the internal shunt resistor which is directly proportional to the primary current. The connector 220 includes a housing 308 that defines a hollow interior. A material of the housing 308 includes an electrical insulating material. As stated previously, the current conductor 224 passes through the hollow interior of the connector 220. The housing 308 includes a first conical portion 304 and a second conical portion 306. The first conical portion 304 is positioned within the interior of the gas insulated switchgear 112 and passes through a flange cover 222 (see FIG. 2) of the pressurized container 204 with the conical shape improving the fluid tight seal that maintains the pressurized fluid. The first conical portion 304 connects the phase conductors of the current conductor 224 to the connecting conductors 228. The second conical portion 306 is positioned on the exterior of the gas insulated switchgear 112 and its conical shape is adapted to connect to a standard cable plug 226. In between the first conical portion 304 and the second conical portion 306, lies a disc-shaped partition 310 which lies flush against the exterior of the flange cover 222.

A shielding mesh 314 is positioned within the hollow interior of the connector 220 and surrounds the current conductor 224. The shielding mesh 314 provides a dielectric shielding to control the electrical field and protect the current conductor 224. The shielding mesh 314 may be made of a metallic mesh. In an embodiment, the metallic mesh comprises a stainless steel. Both the low power instrument transformer 302 and the shielding mesh 314 circumferentially surround (see FIG. 4) and are concentric with the current conductor 224 which lies along a longitudinal axis 322. The shielding mesh 314 may include ends that flare out and away from the current conductor 224 to further protect the low power instrument transformer 302.

Electrical wires 316 carry measured signals of a current sensor 318 and/or a voltage sensor 320 through the disc-shaped partition 310 so that the current and/or the voltage may be displayed to a user. The electrical wires 316 terminate in a merging unit having a processor that collects the current and voltage signals and transmits the current and voltage information to the GIS protection relay. A resin 312 is incorporated into the hollow interior so that the low power instrument transformer 302 and the current conductor 224 are surrounded by the resin 312. The resin 312 provides a further insulating function to the interior components of the connector 220 as well as holding the components in place. The low power instrument transformer 302 may be configured to fit within the first conical portion 304 and the disc-shaped partition 310 of connector 220.

FIG. 4 illustrates a perspective view of the connector 220 of FIG. 3 having a low power instrument transformer 302 integrated within. From this perspective, one can view the voltage sensor 320 circumferentially surrounding the current conductor 224. In between the voltage sensor 320 and the current conductor 224 lies the shielding mesh 314 that also circumferentially surrounds the current conductor 224. The shielding mesh 314 includes a first end and a second end that each flare away from the current conductor 224 further protecting the voltage sensor 320 and the current sensor 318. The current sensor 318 also circumferentially surrounds the current conductor 224 and lies adjacent to the voltage sensor 320 along the longitudinal axis 322 of the current conductor 224. The shielding mesh 314 lies between the current sensor 318 and the current conductor 224.

In an embodiment, the current sensor 318 may be a Rogowski coil. A Rogowski coil is an instrument used to safely measure AC electrical current traveling through a primary conductor such as a cable. In an embodiment, two transformer coils are utilized. When two transformer coils are used, a redundancy of the Rogowski coils exists so that if one fails the other one may be utilized.

In operation, the current sensors 318 inserted within the grooves 602 of the ring-shaped electrodes 502 can relay, via electrical wire 316, a current flow through the respective phase conductor 508, see FIGS. 5 and 6. The ring shaped electrodes 502 are attached to the flange ring 504 via the holder 506. The electrical voltage provided by the voltage sensor 320 can also be relayed via an electrical wire for display and further processing. Utilizing the low power instrument transformer 302 embedded within the conical connector provides a compact design which may be installed in a factory before the installation of the high voltage equipment on site. The current transformer may be utilized to measure the current flowing through the current conductor 224 or to detect an overcurrent, i.e., a current above a threshold, in order to protect the switching device 206. In the case of an overcurrent, from lightning for example, the overcurrent detection can be used to automatically open the switching device 206.

What is claimed is:

1. A sensor arrangement for a gas-insulated switchgear device, comprising:
a connector having a housing defining a hollow interior;
a current conductor passing through the hollow interior of the connector;
a low power instrument transformer comprising:
an electrode having a ring shape and including a voltage sensor for measuring a voltage of the current conductor, and
a current sensor positioned to measure a current of the current conductor;
a shielding field electrode disposed between the current sensor and the current conductor; and
a resin cooperating with and surrounding the current conductor, the voltage sensor, the current sensor and the shielding field electrode to fill the hollow interior.

2. The sensor arrangement as claimed in claim 1, wherein the current sensor is a Rogowski coil that surrounds a current conductor of the low power instrument transformer.

3. The sensor arrangement as claimed in claim 2, wherein the current sensor includes a first Rogowski coil and a second Rogowski coil, wherein the second coil operates in response to a failure of the first Rogowski coil.

4. The sensor arrangement as claimed in claim 1, wherein the shielding field electrode includes a shielding mesh.

5. The sensor arrangement as claimed in claim 4, wherein the shielding mesh comprises a metallic mesh.

6. The sensor arrangement as claimed in claim 1, wherein the shielding field electrode includes a first end and a second end that each flare away from the current conductor.

7. A gas-insulated switchgear device, comprising:
a sensor arrangement as claimed in claim 1.
